(19) United States
(12) Patent Application Publication
(10) Pub. No.: US 2013/0043894 A1
(43) Pub. Date: Feb. 21, 2013

(54) METHOD AND ARRANGEMENT FOR DETERMINING IMPEDANCE VALUES

(71) Applicant: ABB TECHNOLOGY AG, Zurich (FI)

(72) Inventors: Ari WAHLROOS, Vaasa (FI); Janne ALTONEN, Toijala (FI)

(73) Assignee: ABB TECHNOLOGY AG, Zurich (FI)

(21) Appl. No.: 13/654,741

(22) Filed: Oct. 18, 2012

Related U.S. Application Data
(63) Continuation of application No. PCT/EP2011/056011, filed on Apr. 15, 2011.

(30) Foreign Application Priority Data
Apr. 19, 2010 (EP) 10160295.1

(51) Int. Cl. G01R 27/02

(52) U.S. Cl. 324/705

(57) ABSTRACT

A method and an arrangement are provided for determining values of impedance parameters related to a transformer configuration including three single pole voltage transformers each respectively having at least a primary winding, a secondary winding and a tertiary winding. The primary windings are connected to phases of a three phase electric system. The arrangement is configured to conduct an earth fault in the three phase electric system, measure a primary voltage from the faulted phase, measure secondary voltages from the secondary windings, and determine values of one or more impedance parameters related to the transformer configuration on the basis of the measured primary voltage, the measured secondary voltages and an equation relating the primary voltage to the secondary voltages and the one or more impedance parameters.

### RELATED APPLICATION

This application claims priority as a continuation application under 35 U.S.C. §120 to PCT/EP2011/056011, which was filed as an International Application on Apr. 15, 2011 designating the U.S., and which claims priority to European Application 10160295.1 filed in Europe on Apr. 19, 2010. The entire contents of these applications are hereby incorporated by reference in their entireties.

### FIELD

The present disclosure relates to determining impedance values.

### BACKGROUND INFORMATION

Single pole insulated voltage transformers used in electricity distribution networks may be equipped with three windings. In addition to a primary winding, transformers have a secondary winding, for example, a measuring winding, which is used for either measuring or protection purposes, and a tertiary winding, for example, an earth-fault winding, which is utilized for earth-fault protection purposes. The terminals of the primary, measuring and earth-fault windings may be denoted as: A-N, a-n and da-dn, respectively. FIG. 1 shows a terminal diagram of a single pole insulated voltage transformer with three windings. In the illustrated configuration, all three windings are wound around the same magnetic (iron) core. FIG. 2 illustrates a principal construction of an exemplary single pole insulated voltage transformer with three windings, which include a primary winding 20, an earth-fault winding 30 and a measuring winding 40, which are wound around a core 50 and enclosed in a housing 60. The fact that all the windings 20, 30, 40 are wound around the same magnetic core 50 makes the windings interlinked through magnetic fluxes. Consequently, when a primary voltage is applied to the primary winding 20, the secondary windings 30, 40 produce secondary voltages that depend on the primary voltage and a turns-ratio between the secondary winding in question and the primary winding.

In a three-phase network, the earth-fault windings of three single pole insulated voltage transformers may be connected in an “open-delta” connection. This is due to the fact that during an earth-fault in the primary network, the voltage between the open-delta terminals is related to a residual voltage of the network (voltage between earth and neutral point of the three-phase system). This voltage is utilized in earth-fault protection relays. In addition, a resistor may be connected between open-delta terminals in order to provide necessary damping power in case of ferro-resonance. FIG. 3 shows a known configuration of three single pole insulated voltage transformers 11, 12, 13, each with primary windings 21, 22, 23, measuring windings 41, 42, 43 and earth-fault windings 31, 32, 33 connected to phases PA, PB, PC of a three-phase network. Earth-fault windings 31, 32, 33 of the three single pole insulated voltage transformers 11, 12, 13 are connected in an open-delta connection. A resistor Rd is connected between open-delta terminals in order to provide necessary damping power in case of ferro-resonance. The primary voltages of the three phases PA, PB, PC of the three-phase network may then be obtained on the basis of the secondary voltages measured from the measuring windings 41, 42, 43 and the turns-ratio between the primary winding and the measuring winding.

However, inductive voltage transformers may have a limited measurement accuracy compared with, for example, voltage sensors. The accuracy of the inductive voltage transformers is disturbed especially when small amplitude voltages, for example, the faulted phase voltage during earth faults, are being measured. The accuracy of the inductive voltage transformers can be improved by taking into account parameters affecting the accuracy. Such parameters in a transformer configuration of FIG. 3 may include, for example, the following:

Z̅₁=Impedance of the primary winding

Z̅₂=Impedance of the secondary winding

Z̅₃=Impedance of the tertiary winding

Z̅_{ws}=Secondary wiring impedance

Z̅_{wn}=Wiring impedance of the neutral conductor of the secondary burden

Z̅_{wd}=Tertiary wiring impedance

Z̅_{bs}=Secondary burden impedance

Z̅_{bd}=Tertiary burden impedance

Rd=Ferroresonance damping resistance

Parameter Rd, the resistance of a ferro-resonance damping resistor, value is generally known. This is because it is a separate component and it is dimensioned when ordered.

Transformer-related values Z̅₁, Z̅₂ and Z̅₃ are transformer-design-specific. They can be determined by short-circuit impedance tests. However, such tests are not routine tests for voltage transformers. If the transformers are already installed in the substation, the determination of Z̅₁, Z̅₂ and Z̅₃ values is difficult to conduct. Secondary and tertiary circuit related values Z̅_{ws}, Z̅_{wn}, Z̅_{wd}, Z̅_{bs}, Z̅_{bd} might also be challenging to determine in practice. There exists test equipment, which can determine the voltage transformer burden by simple measurement procedure. However, the test equipment is very expensive.

### SUMMARY

An exemplary embodiment of the present disclosure provides a method for determining values of impedance parameters related to a transformer configuration including three single pole voltage transformers each respectively having at least a primary winding, a secondary winding and a tertiary winding. The primary windings are connected to phases of a three phase electric system, and the tertiary windings of the voltage transformers are open-delta connected with each other. The exemplary method includes: a) conducting an earth fault in the three phase electric system by connecting to earth one of the phases of the three phase electric system; b) measuring a primary voltage from the faulted phase; c) measuring secondary voltages from the secondary windings; and d) determining values of one or more impedance parameters related to the transformer configuration on the basis of the measured primary voltage, the measured secondary voltages, and an equation relating the primary voltage to the secondary voltages and the one or more impedance parameters related to the transformer configuration.

An exemplary embodiment arrangement for determining values of impedance parameters related to a transformer configuration including three single pole voltage transformers each respectively having at least a primary winding, a secondary winding and a tertiary winding. The primary windings are connected to phases of a three phase electric system, and the tertiary windings of the voltage transformers are open-delta connected with each other. The exemplary arrangement includes means for conducting an earth fault in the three phase electric system by connecting to earth one of the phases of the three phase electric system, means for measuring a primary voltage from the faulted phase, and means for measuring secondary voltages from the secondary windings. In addition, the exemplary arrangement includes means for determining values of one or more impedance parameters related to the transformer configuration on the basis of the measured primary voltage, the measured secondary voltages, and an equation relating the primary voltage to the secondary voltages and the one or more impedance parameters related to the transformer configuration.

An exemplary embodiment of the present disclosure provides an arrangement for determining values of impedance parameters related to a transformer configuration including three single pole voltage transformers each respectively having at least a primary winding, a secondary winding and a tertiary winding. The primary windings are connected to phases of a three phase electric system, and the tertiary windings of the voltage transformers are open-delta connected with each other. The exemplary arrangement is configured to conduct an earth fault in the three phase electric system by connecting to earth one of the phases of the three phase electric system, measure a primary voltage from the faulted phase, and measure secondary voltages from the secondary windings. In addition, the exemplary arrangement is configured to determine values of one or more impedance parameters related to the transformer configuration on the basis of the measured primary voltage, the measured secondary voltages, and an equation relating the primary voltage to the secondary voltages and the one or more impedance parameters related to the transformer configuration.

An exemplary embodiment of the present disclosure provides an arrangement for determining values of impedance parameters related to a transformer configuration including three single pole voltage transformers each respectively having at least a primary winding, a secondary winding and a tertiary winding. The primary windings are connected to phases of a three phase electric system, and the tertiary windings of the voltage transformers are open-delta connected with each other. The exemplary arrangement includes a processor, and a memory storing instructions that, when executed by the processor, cause the apparatus to: (i) conduct an earth fault in the three phase electric system by connecting to earth one of the phases of the three phase electric system; (ii) measure a primary voltage from the faulted phase; (iii) measure secondary voltages from the secondary windings; and (iv) determine values of one or more impedance parameters related to the transformer configuration on the basis of the measured primary voltage, the measured secondary voltages and an equation relating the primary voltage to the secondary voltages and the one or more impedance parameters related to the transformer configuration.

### BRIEF DESCRIPTION OF THE DRAWINGS

Additional refinements, advantages and features of the present disclosure are described in more detail below with reference to exemplary embodiments illustrated in the drawings, in which:

FIG. 1 shows a terminal diagram of a single pole insulated voltage transformer with three windings;

FIG. 2 shows a principal construction of a single pole insulated voltage transformer with three windings;

FIG. 3 shows a configuration of three single pole insulated voltage transformers each with three windings;

FIG. 4 shows an equivalent circuit of three single pole instrument voltage transformers where secondary burden is star-connected, according to an exemplary embodiment of the present disclosure;

FIG. 5 shows an equivalent circuit of three single pole instrument voltage transformers where secondary burden is delta-connected (after delta-star conversion), according to an exemplary embodiment of the present disclosure; and

FIG. 6 shows an apparatus according to an exemplary embodiment of the present disclosure.

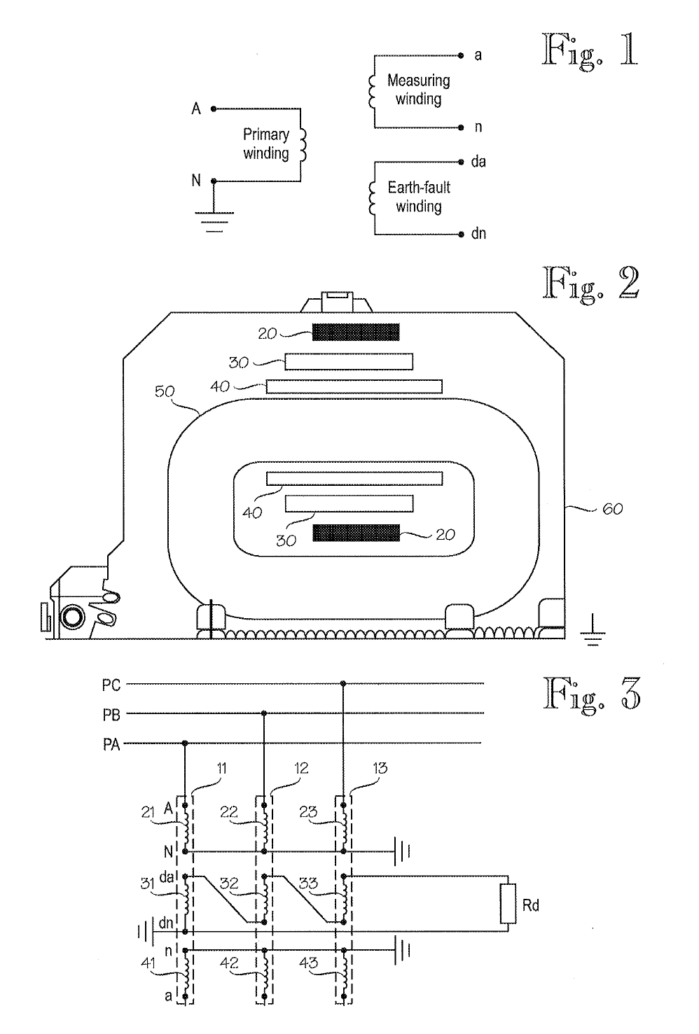

### DETAILED DESCRIPTION

Exemplary embodiments of the present disclosure provide a method and an apparatus for implementing the method so as to overcome the above drawback or at least to alleviate it. The method and arrangement of the present disclosure are described in more detail below.

Exemplary embodiments of the present disclosure are based on the idea of conducting a single-phase trial earth fault in the three phase electric system into which a transformer configuration including three single pole voltage transformers is connected to and measuring a primary voltage from a primary winding connected to the faulted phase and secondary voltages from secondary windings. Values of one or more impedance parameters related to the transformer configuration are then evaluated on the basis of these measured values and an equation relating to each other the primary voltage, the secondary voltages and the one or more impedance parameters related to the transformer configuration. According to an exemplary embodiment, when the number of the impedance parameters whose values are to be evaluated is two or more, an iterative optimization procedure may be utilized to find by iteration such values of the two or more impedance parameters related to the transformer configuration that minimize a difference between the measured value of the primary voltage and a calculated value of the primary voltage, which is calculated on the basis of the equation, the measured secondary voltages and the values of the two or more impedance parameters.

The exemplary method and arrangement of the present disclosure provide that the values for one or more impedance parameters related to the transformer configuration can be determined using a simple arrangement. Because the measurements are made during an earth fault, the determined values for the one or more impedance parameters automatically take into account the conditions and possible measurement inaccuracies and errors during a fault condition due to, for example, voltage transformer characteristics, and thus such determined values provide a compensation for such inaccuracies and errors.

The application of the present disclosure is not limited to any specific system, but it can be used in connection with various electric systems. Moreover, the use of the present disclosure is not limited to systems or devices employing any specific fundamental frequency or any specific voltage level.

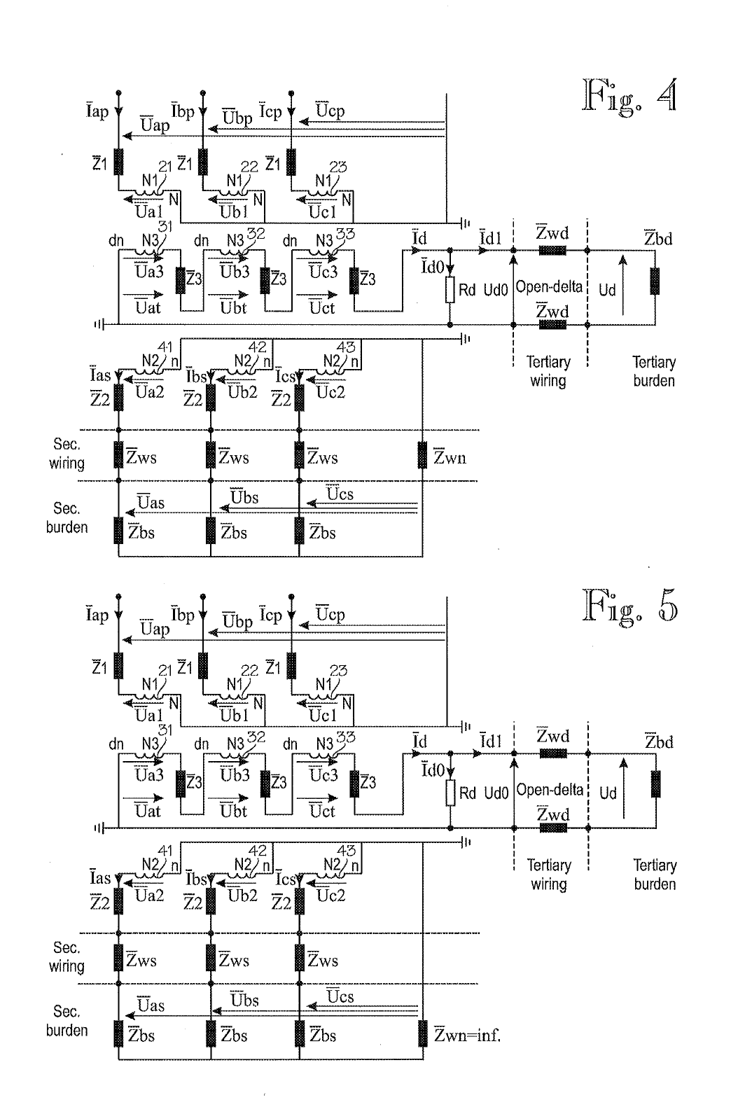

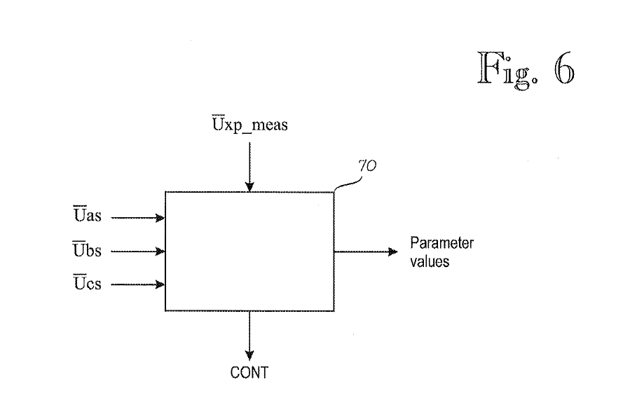

In order to analyze the behavior of an exemplary configuration of three single pole insulated voltage transformers with three windings in a three-phase network, the electrical equivalent schemes of FIGS. 4 and 5 can be derived.

The secondary burden (impedance Z̅_{bs}) is connected to transformers' secondary (measuring) winding 41, 42, 43 terminals. The connection is made through wiring impedance Z̅_{ws}. FIG. 4 illustrates a star-connected burden, where the common neutral conductor is modeled with wiring impedance Z̅_{wn}. The equivalent scheme presented in FIG. 5 can be used in case the burden is delta connected. In this case the neutral conductor impedance Z̅_{wn} equals infinity. Z̅_{bs} values can be obtained using delta-star conversion for impedances.

The tertiary (earth-fault) windings 31, 32, 33 are connected in an “open-delta” configuration for earth-fault protection purposes. Resistor Rd is connected between open-delta terminals in order to prevent ferro-resonance. Tertiary burden (impedance Z̅_{bd}) is connected to transformers' tertiary terminals. The connection is made through wiring impedance Z̅_{wd}.

Notations used in FIGS. 4 and 5:

Ūₐₚ=Phase PA primary phase-to-earth voltage

Ū_{bp}=Phase PB primary phase-to-earth voltage

Ū_{cp}=Phase PC primary phase-to-earth voltage

Ūₐₛ=Phase PA secondary phase-to-earth voltage

Ū_{bs}=Phase PB secondary phase-to-earth voltage

Ū_{cs}=Phase PC secondary phase-to-earth voltage

Ūₐₜ=Phase PA tertiary phase-to-earth voltage

Ū_{bt}=Phase PB tertiary phase-to-earth voltage

Ū_{ct}=Phase PC tertiary phase-to-earth voltage

Z̅₁=Impedance of the primary winding

Z̅₂=Impedance of the secondary winding

Z̅₃=Impedance of the tertiary winding

Z̅_{ws}=Secondary wiring impedance

Z̅_{wn}=Wiring impedance of the neutral conductor of the secondary burden

Z̅_{wd}=Tertiary wiring impedance

Z̅_{bs}=Secondary burden impedance

Z̅_{bd}=Tertiary burden impedance

Rd=Ferro-resonance damping resistance

N1=Number of turns of wire in the primary winding

N2=Number of turns of wire in the secondary winding

N3=Number of turns of wire in the tertiary winding

Īₐₚ=Phase PA primary phase current

Ī_{bp}=Phase PB primary phase current

Ī_{cp}=Phase PC primary phase current

Īₐₛ=Phase PA secondary phase current

Ī_{bs}=Phase PB secondary phase current

Ī_{cs}=Phase PC secondary phase current

Ūₐ₁=Voltage over the primary winding, phase PA

Ū_{b1}=Voltage over the primary winding, phase PB

Ū_{c1}=Voltage over the primary winding, phase PC

Ūₐ₂=Voltage over the secondary winding, phase PA

Ū_{b2}=Voltage over the secondary winding, phase PB

Ū_{c2}=Voltage over the secondary winding, phase PC

Ūₐ₃=Voltage over the tertiary winding, phase PA

Ū_{b3}=Voltage over the tertiary winding, phase PB

Ū_{c3}=Voltage over the tertiary winding, phase PC

Ī_{d0}=Tertiary current through the damping resistor

Ī_{d1}=Tertiary current through the tertiary burden

Ī_{d}=Total tertiary current

Ū_{d}=Open-delta voltage

Ū_{d0}=Voltage over the damping resistor=Ūₐₜ+Ū_{bt}+Ū_{ct}

The transformers are modeled with their respective longitudinal impedances Z̅₁, Z̅₂ and Z̅₃, which include a winding resistance and a leakage reactance. These are assumed to be similar for each phase transformer. Values for Z̅₁, Z̅₂ and Z̅₃ can be derived from short-circuit test results or obtained from the manufacturer of the transformer, for example. The effect of an external cabling/wiring for instrumentation can be taken into account by wiring impedances Z̅_{ws}, Z̅_{wn} and Z̅_{wd}. Burden can be taken into account with impedances Z̅_{bs} and Z̅_{bd}. From FIGS. 4 and 5, the following equations can be written (equations with “a” apply for FIG. 4, equations with “b” apply for FIG. 5):

Phase a:

Ūap − Z̅1*Īap=Ūa1 (eq 1)

Ūa2−( Z̅2+ Z̅ws)*Īas=Ūas+ Z̅wn*(Īas+Ībs+Īcs) (eq 2a)

Ūa2−( Z̅2+ Z̅ws)*Īas=Ūas (eq 2b)

Ūa3− Z̅3*Īd=Ūat (eq 3)

N1*Īap=N2*Īas+N3*Īd (eq 4)

Ūas= Z̅bs*Īas (eq 5a)

Ūas= Z̅bs*Īas+ Z̅wn*(Īas+Ībs+Īcs) (eq 5b)

Ūa2=(N2/N1)*Ūa1 (eq 6)

Ūa3=(N3/N1)*Ūa1 (eq 7)

Phase b:

Ūbp− Z̅1*Ībp=Ūb1 (eq 8)

Ūb2−( Z̅2+ Z̅ws)*Ībs=Ūbs+ Z̅wn*(Īas+Ībs+Īcs) (eq 9a)

Ūb2( Z̅2+ Z̅ws)*Ībs=Ūbs (eq 9b)

Ūb3− Z̅3*Īd=Ūbt (eq 10)

N1*Ībp=N2*Ībs+N3*Id (eq 11)

Ūbs= Z̅bs*Ībs (eq 12a)

Ūbs= Z̅bs*Ībs+ Z̅wn*(Īas+Ībs+Īcs) (eq 12b)

Ūb2=(N2/N1)*Ūb1 (eq 13)

Ūb3=(N3/N1)*Ūb1 (eq 14)

Phase c:

Ūcp− Z̅1*Īcp=Ūc1 (eq 15)

Ūc2−( Z̅2+ Z̅ws)*Īcs=Ūcs+ Z̅wn*(Īas+Ībs+Īcs) (eq 16a)

Ūc2−( Z̅2+ Z̅ws)*Īcs=Ūcs (eq 16b)

Ūc3− Z̅3*Īd=Ūct (eq 17)

N1*Īcp=N2*Īcs+N3*Īd (eq 18)

Ūcs= Z̅bs*Īcs (eq 19a)

Ūcs= Z̅bs*Īcs+ Z̅wn*(Īas+Ībs+Īcs) (eq 19b)

Ūc2=(N2/N1)*Ūc1 (eq 20)

Ūc3=(N3/N1)*Ūc1 (eq 21)

And

Īd0*Rd=(Ūat+Ūbt+Ūct) (eq 22)

Īd0*Rd− Z̅wd*Īd1=( Z̅bd+ Z̅wd)*Īd1 (eq 23)

Īd=Īd0+Īd1 (eq 24)

In equations 1 to 24, the known voltages are assumed to be:

Ūₐₛ=Phase PA secondary phase-to-earth voltage

Ū_{bs}=Phase PB secondary phase-to-earth voltage

Ū_{cs}=Phase PC secondary phase-to-earth voltage

The known impedances and transformer-related values are:

Z̅₁=Impedance of the primary winding

Z̅₂=Impedance of the secondary winding

Z̅₃=Impedance of the tertiary winding

Z̅_{ws}=Wiring impedance of the secondary circuit

Z̅_{wn}=Wiring impedance of the secondary circuit, neutral conductor

Z̅_{wd}=Wiring impedance of the open delta

Z̅_{bs}=Secondary burden impedance

Z̅bd=Tertiary burden impedance

Rd=Ferro-resonance damping resistance

N1=Number of turns of wire in the primary winding

N2=Number of turns of wire in the secondary winding

N3=Number of turns of wire in the tertiary winding

All other voltages and currents can be calculated as a function of secondary phase-to-earth voltage and known impedances and transformer-related values. Thus, accurate primary phase-to-earth voltages can be obtained: In case the secondary burden is star-connected and the common neutral conductor wiring impedance is Z̅_{wn} (refer to FIG. 4), equations 25-27 apply:

Ūₐₚ=1/N2/ Z̅_{bs}*(3*N1^{2*} Z̅_{wn}*Ūₐₛ*Rd* Z̅₃₊₆*N1²* Z̅_{wn}*Ūₐₛ* Z̅₃* Z̅_{wd+3}*N1²* Z̅_{wn}*Ūₐₛ* Z̅₃* Z̅_{bd+2}*N1²* Z̅_{wn}*Ūₐₛ*Rd* Z̅_{wd}+N1²* Z̅_{wn}*Ūₐₛ*Rd* Z̅_{bd}+3*N1²* Z̅_{wn}*Ū_{bs}*Rd* Z̅₃₊₆*N1²* Z̅_{wn}*Ū_{bs}* Z̅₃* Z̅_{wd}+3*N1²* Z̅_{wn}*Ū_{bs}* Z̅₃* Z̅_{bd}+2*N1²* Z̅_{wn}*Ū_{bs}*Rd* Z̅_{wd}+N1²* Z̅_{wn}*Ū_{bs}*Rd* Z̅_{bd}+3*N1²* Z̅_{wn}*Ū_{cs}*Rd* Z̅₃+6*N1²* Z̅_{wn}*Ū_{cs}* Z̅₃* Z̅_{wd}3*N1²* Z̅_{wn}*Ū_{cs}* Z̅₃* Z̅_{bd}+2*N1²* Z̅_{wn}*Ū_{cs}*Rd* Z̅_{wd}+N1²* Z̅_{wn}*Ū_{cs}*Rd* Z̅_{bd}+2* Z̅₁*N3²* Z̅_{wd}*Ū_{bs}* Z̅_{bs}+3* Z̅₁*N3²* Z̅_{bd}* Z̅_{wn}*Ū_{bs}+ Z̅₁*N3²* Z̅_{bd}*Ūₐₛ* Z̅_{ws}+3* Z̅₁*N3²* Z̅_{bd}* Z̅_{wn}*Ūₐₛ+ Z̅₁*N3²* Z̅_{bd}*Ūₐₛ* Z̅₂+ Z̅₁*N3²* Z̅_{bd}*Ūₐₛ* Z̅_{bs}+ Z̅₁*N3²*Rd*Ūₐₛ* Z̅_{bs}+6* Z̅₁*N3²* Z̅_{wd}* Z̅_{wn}*Ū_{cs}+3* Z̅₁*N3²* Z̅_{bd}* Z̅_{wn}*Ū_{cs}+ Z̅₁*N3²* Z̅_{bd}*Ū_{bs}* Z̅₂+ Z̅₁*N3²* Z̅_{bd}*Ū_{cs}* Z̅₂+ Z̅₁*N3²* Z̅_{bd}*Ū_{cs}* Z̅_{ws}+ Z̅₁*N3²* Z̅_{bd}*Ū_{cs}* Z̅_{bs}+ Z̅₁*N3²* Z̅_{bd}*Ū_{bs}* Z̅_{ws}+ Z̅₁*N3²* Z̅_{bd}*Ū_{bs}* Z̅_{bs}+ ^{Z̅}₁*N3²*Rd*Ūₐₛ* Z̅₂+ Z̅₁*N3²*Rd*Ūₐₛ* Z̅_{ws}+3* Z̅₁*N3²*Rd* Z̅_{wn}*Ūₐₛ+3* Z̅₁*N3²*Rd* Z̅_{wn}*Ū_{bs}+3* Z̅₁*N3²*Rd* Z̅_{wn}*Ū_{cs}+ Z̅₁*N3²*Rd*Ū_{bs}* Z̅₂+ Z̅₁*N3²*Rd*Ū_{cs}* Z̅₂+ Z̅₁*N3²*Rd*Ū_{cs}* Z̅_{ws}+ Z̅₁*N3²*Rd*Ū_{cs}* Z̅_{bs}+ Z̅₁*N3²*Rd*Ū_{bs}* Z̅_{ws}+ Z̅₁*N3²*Rd*Ū_{bs}* Z̅_{bs}+2* Z̅₁*N3²* Z̅_{wd}*Ūₐₛ* Z̅₂+2* Z̅₁*N3²* Z̅_{wd}*Ūₐₛ* Z̅_{ws}+2* Z̅₁*N3²* Z̅_{wd}*Ūₐₛ* Z̅_{bs}+6* Z̅₁*N3²* Z̅_{wd}* Z̅_{wn}*Ūₐₛ+6* Z̅₁*N3²* Z̅_{wd}* Z̅_{wn}*Ū_{bs}+2* Z̅₁*N3²* Z̅_{wd}*Ū_{bs}* Z̅₂+2* Z̅₁*N3²* Z̅_{wd}*Ū_{cs}* Z̅_{ws}+2* Z̅₁*N3²* Z̅_{wd}*Ū_{cs}* Z̅_{bs}+2* Z̅₁*N3²* Z̅_{wd}*Ū_{bs}* Z̅_{ws}+2* Z̅₁*N3²* Z̅_{wd}*Ū_{cs}* Z̅₂+3*N1²*Ūₐₛ* Z̅₂*Rd* Z̅₃+6*N1²*Ūₐₛ* Z̅₂* Z̅₃* Z̅_{wd}+3*N1²*Ūₐₛ* Z̅₂* Z̅₃* Z̅_{bd}+2*N1²*Ūₐₛ* Z̅₂*Rd* Z̅_{wd}+N1²*Ūₐₛ* Z̅₂*Rd* Z̅_{bd}+3*N1²*Ūₐₛ* Z̅_{ws}*Rd* Z̅₃+6*N1²*Ūₐₛ* Z̅_{ws}* Z̅₃* Z̅_{wd}+3*N1²*Ūₐₛ* Z̅_{ws}* Z̅₃* Z̅_{bd}+2*N1²*Ūₐₛ* Z̅_{ws}*Rd* Z̅_{wd}+N1²*Ūₐₛ* Z̅_{ws}*Rd* Z̅_{bd}+3*N1²*Ūₐₛ* Z̅_{bs}*Rd* Z̅₃+6*N1²*Ūₐₛ* Z̅_{bs}* Z̅₃* Z̅_{wd}+3*N1²*Ūₐₛ* Z̅_{bs}* Z̅₃* Z̅_{bd}+2*N1²*Ūₐₛ* Z̅_{bs}*Rd* Z̅_{wd}+N1²*Ūₐₛ* Z̅_{bs}*Rd* Z̅_{bd}+3* Z̅₁*N2²*Ūₐₛ*Rd* Z̅₃+6* Z̅₁*N2²*Ūₐₛ* Z̅₃* Z̅_{wd}+3* Z̅₁*N2²*Ūₐₛ* Z̅₃* Z̅_{bd}+2* Z̅₁*N2²*Ūₐₛ*Rd* Z̅_{wd}+ Z̅₁*N2²*Ūₐₛ*Rd* Z̅_{bd})/N1/(3*Rd* Z̅₃+6* Z̅₃* Z̅_{wd}+3* Z̅₃* Z̅_{bd}+2*Rd* Z̅_̅{̅w̅d̅}̅+Rd* Z̅_{bd}) (Eq. 25)

Ū_{bp}=1/N2/ Z̅_{bs}*(3*N1^{2*} Z̅_{wn}*Ūₐₛ*Rd* Z̅₃₊₆*N1²* Z̅_{wn}*Ūₐₛ* Z̅₃* Z̅_{wd+3}*N1²* Z̅_{wn}*Ūₐₛ* Z̅₃* Z̅_{bd+2}*N1²* Z̅_{wn}*Ūₐₛ*Rd* Z̅_{wd}+N1²* Z̅_{wn}*Ūₐₛ*Rd* Z̅_{bd}+3*N1²* Z̅_{wn}*Ū_{bs}*Rd* Z̅₃₊₆*N1²* Z̅_{wn}*Ū_{bs}* Z̅₃* Z̅_{wd}+3*N1²* Z̅_{wn}*Ū_{bs}* Z̅₃* Z̅_{bd}+2*N1²* Z̅_{wn}*Ū_{bs}*Rd* Z̅_{wd}+N1²* Z̅_{wn}*Ū_{bs}*Rd* Z̅_{bd}+3*N1²* Z̅_{wn}*Ū_{cs}*Rd* Z̅₃+6*N1²* Z̅_{wn}*Ū_{cs}* Z̅₃* Z̅_{wd}3*N1²* Z̅_{wn}*Ū_{cs}* Z̅₃* Z̅_{bd}+2*N1²* Z̅_{wn}*Ū_{cs}*Rd* Z̅_{wd}+N1²* Z̅_{wn}*Ū_{cs}*Rd* Z̅_{bd}+2* Z̅₁*N3²* Z̅_{wd}*Ū_{bs}* Z̅_{bs}+3* Z̅₁*N3²* Z̅_{bd}* Z̅_{wn}*Ū_{bs}+ Z̅₁*N3²* Z̅_{bd}*Ūₐₛ* Z̅_{ws}+3* Z̅₁*N3²* Z̅_{bd}* Z̅_{wn}*Ūₐₛ+ Z̅₁*N3²* Z̅_{bd}*Ūₐₛ* Z̅₂+ Z̅₁*N3²* Z̅_{bd}*Ūₐₛ* Z̅_{bs}+ Z̅₁*N3²*Rd*Ūₐₛ* Z̅_{bs}+6* Z̅₁*N3²* Z̅_{wd}* Z̅_{wn}*Ū_{cs}+3* Z̅₁*N3²* Z̅_{bd}* Z̅_{wn}*Ū_{cs}+ Z̅₁*N3²* Z̅_{bd}*Ū_{bs}* Z̅₂+ Z̅₁*N3²* Z̅_{bd}*Ū_{cs}* Z̅₂+ Z̅₁*N3²* Z̅_{bd}*Ū_{cs}* Z̅_{ws}+ Z̅₁*N3²* Z̅_{bd}*Ū_{cs}* Z̅_{bs}+ Z̅₁*N3²* Z̅_{bd}*Ū_{bs}* Z̅_{ws}+ Z̅₁*N3²* Z̅_{bd}*Ū_{bs}* Z̅_{bs}+ ^{Z̅}₁*N3²*Rd*Ūₐₛ* Z̅₂+ Z̅₁*N3²*Rd*Ūₐₛ* Z̅_{ws}+3* Z̅₁*N3²*Rd* Z̅_{wn}*Ūₐₛ+3* Z̅₁*N3²*Rd* Z̅_{wn}*Ū_{bs}+3* Z̅₁*N3²*Rd* Z̅_{wn}*Ū_{cs}+ Z̅₁*N3²*Rd*Ū_{bs}* Z̅₂+ Z̅₁*N3²*Rd*Ū_{cs}* Z̅₂+ Z̅₁*N3²*Rd*Ū_{cs}* Z̅_{ws}+ Z̅₁*N3²*Rd*Ū_{cs}* Z̅_{bs}+ Z̅₁*N3²*Rd*Ū_{bs}* Z̅_{ws}+ Z̅₁*N3²*Rd*Ū_{bs}* Z̅_{bs}+2* Z̅₁*N3²* Z̅_{wd}*Ūₐₛ* Z̅₂+2* Z̅₁*N3²* Z̅_{wd}*Ūₐₛ* Z̅_{ws}+2* Z̅₁*N3²* Z̅_{wd}*Ūₐₛ* Z̅_{bs}+6* Z̅₁*N3²* Z̅_{wd}* Z̅_{wn}*Ūₐₛ+6* Z̅₁*N3²* Z̅_{wd}* Z̅_{wn}*Ū_{bs}+2* Z̅₁*N3²* Z̅_{wd}*Ū_{bs}* Z̅₂+2* Z̅₁*N3²* Z̅_{wd}*Ū_{cs}* Z̅_{ws}+2* Z̅₁*N3²* Z̅_{wd}*Ū_{cs}* Z̅_{bs}+2* Z̅₁*N3²* Z̅_{wd}*Ū_{bs}* Z̅_{ws}+2* Z̅₁*N3²* Z̅_{wd}*Ū_{cs}* Z̅₂+3*N1²*Ūₐₛ* Z̅₂*Rd* Z̅₃+6*N1²*Ūₐₛ* Z̅₂* Z̅₃* Z̅_{wd}+3*N1²*Ūₐₛ* Z̅₂* Z̅₃* Z̅_{bd}+2*N1²*Ūₐₛ* Z̅₂*Rd* Z̅_{wd}+N1²*Ūₐₛ* Z̅₂*Rd* Z̅_{bd}+3*N1²*Ūₐₛ* Z̅_{ws}*Rd* Z̅₃+6*N1²*Ūₐₛ* Z̅_{ws}* Z̅₃* Z̅_{wd}+3*N1²*Ūₐₛ* Z̅_{ws}* Z̅₃* Z̅_{bd}+2*N1²*Ūₐₛ* Z̅_{ws}*Rd* Z̅_{wd}+N1²*Ūₐₛ* Z̅_{ws}*Rd* Z̅_{bd}+3*N1²*Ūₐₛ* Z̅_{bs}*Rd* Z̅₃+6*N1²*Ūₐₛ* Z̅_{bs}* Z̅₃* Z̅_{wd}+3*N1²*Ūₐₛ* Z̅_{bs}* Z̅₃* Z̅_{bd}+2*N1²*Ūₐₛ* Z̅_{bs}*Rd* Z̅_{wd}+N1²*Ūₐₛ* Z̅_{bs}*Rd* Z̅_{bd}+3* Z̅₁*N2²*Ūₐₛ*Rd* Z̅₃+6* Z̅₁*N2²*Ūₐₛ* Z̅₃* Z̅_{wd}+3* Z̅₁*N2²*Ūₐₛ* Z̅₃* Z̅_{bd}+2* Z̅₁*N2²*Ūₐₛ*Rd* Z̅_{wd}+ Z̅₁*N2²*Ūₐₛ*Rd* Z̅_{bd})/N1/(3*Rd* Z̅₃+6* Z̅₃* Z̅_{wd}+3* Z̅₃* Z̅_{bd}+2*Rd* Z̅_{wd}+Rd* Z̅_{bd}) (Eq. 26)

Ū_{cp}=1/N2/ Z̅_{bs}*(3*N1^{2*} Z̅_{wn}*Ūₐₛ*Rd* Z̅₃₊₆*N1²* Z̅_{wn}*Ūₐₛ* Z̅₃* Z̅_{wd+3}*N1²* Z̅_{wn}*Ūₐₛ* Z̅₃* Z̅_{bd+2}*N1²* Z̅_{wn}*Ūₐₛ*Rd* Z̅_{wd}+N1²* Z̅_{wn}*Ūₐₛ*Rd* Z̅_{bd}+3*N1²* Z̅_{wn}*Ū_{bs}*Rd* Z̅₃₊₆*N1²* Z̅_{wn}*Ū_{bs}* Z̅₃* Z̅_{wd}+3*N1²* Z̅_{wn}*Ū_{bs}* Z̅₃* Z̅_{bd}+2*N1²* Z̅_{wn}*Ū_{bs}*Rd* Z̅_{wd}+N1²* Z̅_{wn}*Ū_{bs}*Rd* Z̅_{bd}+3*N1²* Z̅_{wn}*Ū_{cs}*Rd* Z̅₃+6*N1²* Z̅_{wn}*Ū_{cs}* Z̅₃* Z̅_{wd}3*N1²* Z̅_{wn}*Ū_{cs}* Z̅₃* Z̅_{bd}+2*N1²* Z̅_{wn}*Ū_{cs}*Rd* Z̅_{wd}+N1²* Z̅_{wn}*Ū_{cs}*Rd* Z̅_{bd}+2* Z̅₁*N3²* Z̅_{wd}*Ū_{bs}* Z̅_{bs}+3* Z̅₁*N3²* Z̅_{bd}* Z̅_{wn}*Ū_{bs}+ Z̅₁*N3²* Z̅_{bd}*Ūₐₛ* Z̅_{ws}+3* Z̅₁*N3²* Z̅_{bd}* Z̅_{wn}*Ūₐₛ+ Z̅₁*N3²* Z̅_{bd}*Ūₐₛ* Z̅₂+ Z̅₁*N3²* Z̅_{bd}*Ūₐₛ* Z̅_{bs}+ Z̅₁*N3²*Rd*Ūₐₛ* Z̅_{bs}+6* Z̅₁*N3²* Z̅_{wd}* Z̅_{wn}*Ū_{cs}+3* Z̅₁*N3²* Z̅_{bd}* Z̅_{wn}*Ū_{cs}+ Z̅₁*N3²* Z̅_{bd}*Ū_{bs}* Z̅₂+ Z̅₁*N3²* Z̅_{bd}*Ū_{cs}* Z̅₂+ Z̅₁*N3²* Z̅_{bd}*Ū_{cs}* Z̅_{ws}+ Z̅₁*N3²* Z̅_{bd}*Ū_{cs}* Z̅_{bs}+ Z̅₁*N3²* Z̅_{bd}*Ū_{bs}* Z̅_{ws}+ Z̅₁*N3²* Z̅_{bd}*Ū_{bs}* Z̅_{bs}+ ^{Z̅}₁*N3²*Rd*Ūₐₛ* Z̅₂+ Z̅₁*N3²*Rd*Ūₐₛ* Z̅_{ws}+3* Z̅₁*N3²*Rd* Z̅_{wn}*Ūₐₛ+3* Z̅₁*N3²*Rd* Z̅_{wn}*Ū_{bs}+3* Z̅₁*N3²*Rd* Z̅_{wn}*Ū_{cs}+ Z̅₁*N3²*Rd*Ū_{bs}* Z̅₂+ Z̅₁*N3²*Rd*Ū_{cs}* Z̅₂+ Z̅₁*N3²*Rd*Ū_{cs}* Z̅_{ws}+ Z̅₁*N3²*Rd*Ū_{cs}* Z̅_{bs}+ Z̅₁*N3²*Rd*Ū_{bs}* Z̅_{ws}+ Z̅₁*N3²*Rd*Ū_{bs}* Z̅_{bs}+2* Z̅₁*N3²* Z̅_{wd}*Ūₐₛ* Z̅₂+2* Z̅₁*N3²* Z̅_{wd}*Ūₐₛ* Z̅_{ws}+2* Z̅₁*N3²* Z̅_{wd}*Ūₐₛ* Z̅_{bs}+6* Z̅₁*N3²* Z̅_{wd}* Z̅_{wn}*Ūₐₛ+6* Z̅₁*N3²* Z̅_{wd}* Z̅_{wn}*Ū_{bs}+2* Z̅₁*N3²* Z̅_{wd}*Ū_{bs}* Z̅₂+2* Z̅₁*N3²* Z̅_{wd}*Ū_{cs}* Z̅_{ws}+2* Z̅₁*N3²* Z̅_{wd}*Ū_{cs}* Z̅_{bs}+2* Z̅₁*N3²* Z̅_{wd}*Ū_{bs}* Z̅_{ws}+2* Z̅₁*N3²* Z̅_{wd}*Ū_{cs}* Z̅₂+3*N1²*Ūₐₛ* Z̅₂*Rd* Z̅₃+6*N1²*Ūₐₛ* Z̅₂* Z̅₃* Z̅_{wd}+3*N1²*Ūₐₛ* Z̅₂* Z̅₃* Z̅_{bd}+2*N1²*Ūₐₛ* Z̅₂*Rd* Z̅_{wd}+N1²*Ūₐₛ* Z̅₂*Rd* Z̅_{bd}+3*N1²*Ūₐₛ* Z̅_{ws}*Rd* Z̅₃+6*N1²*Ūₐₛ* Z̅_{ws}* Z̅₃* Z̅_{wd}+3*N1²*Ūₐₛ* Z̅_{ws}* Z̅₃* Z̅_{bd}+2*N1²*Ūₐₛ* Z̅_{ws}*Rd* Z̅_{wd}+N1²*Ūₐₛ* Z̅_{ws}*Rd* Z̅_{bd}+3*N1²*Ūₐₛ* Z̅_{bs}*Rd* Z̅₃+6*N1²*Ūₐₛ* Z̅_{bs}* Z̅₃* Z̅_{wd}+3*N1²*Ūₐₛ* Z̅_{bs}* Z̅₃* Z̅_{bd}+2*N1²*Ūₐₛ* Z̅_{bs}*Rd* Z̅_{wd}+N1²*Ūₐₛ* Z̅_{bs}*Rd* Z̅_{bd}+3* Z̅₁*N2²*Ūₐₛ*Rd* Z̅₃+6* Z̅₁*N2²*Ūₐₛ* Z̅₃* Z̅_{wd}+3* Z̅₁*N2²*Ūₐₛ* Z̅₃* Z̅_{bd}+2* Z̅₁*N2²*Ūₐₛ*Rd* Z̅_{wd}+ Z̅₁*N2²*Ūₐₛ*Rd* Z̅_{bd})/N1/(3*Rd* Z̅₃+6* Z̅₃* Z̅_{wd}+3* Z̅₃* Z̅_{bd}+2*Rd* Z̅_{wd}+Rd* Z̅_{bd}) (Eq. 27)

In case the secondary burden is delta connected, the equivalent scheme of FIG. 5 can be utilized. The neutral conductor impedance Z̅_{wn} then equals infinity. Z̅_{bs} values can be obtained using delta-star conversion for impedances. Equations 28-30 apply:

Ūₐₚ=1/3*(−3*N1²* Z̅₃*Rd* Z̅_{ws}*Ū_{cs}+6*N1²* Z̅₃*Rd* Z̅₂*Ūₐₛ−3*N1²* Z̅₃*Rd* Z̅₂*Ū_{bs}−3*N1²* Z̅₃* Z̅_{bd}* Z̅₂*Ū_{bs}−3*N1²* Z̅₃* Z̅_{bd}* Z̅_{ws}*Ū_{cs}−6*N1²* Z̅₃* Z̅_{wd}* Z̅₂*Ū_{cs}+12*N1²* Z̅₃* Z̅_{wd}* Z̅_{ws}*Ūₐₛ−6*N1²* Z̅₃* Z̅_{wd}* Z̅_{ws}*Ū_{bs}+6*N1²* Z̅₃* Z̅_{bd}* Z̅₂*Ūₐₛ+3* Z̅_{bs}* Z̅₁*N3²* Z̅_{bd}*Ūₐₛ+6*N1²* Z̅₃*Rd* Z̅_{ws*Ū}ₐₛ−3*N1²* Z̅₃*Rd* Z̅_{ws}*Ū_{bs}−N1²* Z̅₂*Ū_{cs}*Rd* Z̅_{bd}−2*N1²* Z̅₂*Ū_{cs}*Rd* Z̅_{wd}+3* Z̅_{bs}* Z̅₁*N3²* Z̅_{bd}*Ū_{bs}+6* Z̅_{bs}* Z̅₁*N3²* Z̅_{wd}*Ū_{cs}+6* Z̅_{bs}* Z̅₁*N3²* Z̅_{wd}*Ūₐₛ−3*N1²* Z̅₃*Rd* Z̅₂*Ū_{cs}+6* Z̅_{bs}* Z̅₁*N3²* Z̅_{wd}*Ū_{bs}+3* Z̅_{bs}* Z̅₁*N3²*Rd*Ū_{cs}+3* Z̅_{bs}* Z̅₁*N3²* Z̅_{bd}*Ū_{cs}+3* Z̅_{bs}* Z̅₁*N3²*Rd*Ū_{bs}+3* Z̅_{bs}* Z̅₁*N3²*Rd*Ūₐₛ+18* Z̅_{bs}*N1²* Z̅₃* Z̅_{wd}*Ūₐₛ+3* Z̅_{bs}*N1²*Ūₐₛ*Rd* Z̅_{bd}−6*N1²* Z̅₃* Z̅_{wd}* Z̅_{ws}*Ū_{cs}+6* Z̅_{bs}*N1²*Ūₐₛ*Rd* Z̅_{wd}+9* Z̅_{bs}*N1²* Z̅₃*Rd*Ūₐₛ+9* Z̅_{bs}*N1²* Z̅₃* Z̅_{bd}*Ūₐₛ−3* Z̅₁*N2²*Ū_{cs}*Rd* Z̅₃+12* Z̅₁*N2²*Ūₐₛ* Z̅_{wd}* Z̅₃−3* Z̅₁*N₂²*Ū_{cs}* Z̅_{bd}* Z̅₃−6* Z̅₁*N2²*Ū_{cs}* Z̅_{wd}* Z̅₃+2* Z̅₁*N2²*Ūₐₛ*Rd* Z̅_{bd}+4* Z̅₁*N2²*Ūₐₛ*Rd* Z̅_{wd}+6* Z̅₁*N2²*Ūₐₛ* Z̅_{bd}* Z̅₃− Z̅₁*N2²*Ū_{cs}*Rd* Z̅_{bd}−2* Z̅₁*N2²*Ū_{cs}*Rd* Z̅_{wd}−3* Z̅₁*N2²*Ū_{bs}*Rd* Z̅₃−N1²* Z̅_{ws}*Ū_{bs}*Rd* Z̅_{bd}−6*N1²* Z̅₃* Z̅_{wd}* Z̅₂*Ū_{bs}−2*N1²* Z̅_{ws}*Ū_{bs}*Rd* Z̅_{wd}+6* Z̅₁*N2²*Ūₐₛ*Rd* Z̅₃+12*N1²* Z̅₃* Z̅_{wd}* Z̅₂*Ūₐₛ−6* Z̅₁*N2²*Ū_{bs}* Z̅_{wd}* Z̅₃−2* Z̅₁*N2²*Ū_{bs}*Rd* Z̅_{wd}−3* Z̅₁*N2²*Ū_{bs}* Z̅_{bd}* Z̅₃−2*N1²* Z̅_{ws}*Ū_{cs}*Rd* Z̅_{wd}+2*N1²* Z̅₂*Ūₐₛ*Rd* Z̅_{bd}+4*N1²* Z̅₂*Ūₐₛ*Rd* Z̅_{wd}− Z̅₁*N2²*Ū_{bs}*Rd* Z̅_{bd}−N1²* Z̅_{ws}*Ū_{cs}*Rd* Z̅_{bd}−3*N1²* Z̅₃* Z̅_{bd}* Z̅_{ws}*Ū_{bs}−N1²* Z̅₂*Ū_{bs}*Rd* Z̅_{bd}−2*N1²* Z̅₂*Ū_{bs}*Rd* Z̅_{wd}+2*N1²* Z̅_{ws}*Ūₐₛ*Rd* Z̅_{bd}+4*N1²* Z̅_{ws}*Ūₐₛ*Rd* Z̅_{wd}−3*N1²* Z̅₃* Z̅_{bd}* Z̅₂*Ū_{cs}+6*N1²* Z̅₃* Z̅_{bd}* Z̅_{ws}*Ūₐₛ)/N1/ Z̅_{bs}/N2/(6* Z̅_{wd}* Z̅₃+3* Z̅_{bd}* Z̅₃+2*Rd* Z̅_{wd}+Rd* Z̅_{bd}+3*Rd* Z̅₃) (Eq. 28)

Ūₐₚ=1/3*(−3*N1²* Z̅₃*Rd* Z̅_{ws}*Ū_{cs}+6*N1²* Z̅₃*Rd* Z̅₂*Ūₐₛ−3*N1²* Z̅₃*Rd* Z̅₂*Ū_{bs}−3*N1²* Z̅₃* Z̅_{bd}* Z̅₂*Ū_{bs}−3*N1²* Z̅₃* Z̅_{bd}* Z̅_{ws}*Ū_{cs}−6*N1²* Z̅₃* Z̅_{wd}* Z̅₂*Ū_{cs}+12*N1²* Z̅₃* Z̅_{wd}* Z̅_{ws}*Ūₐₛ−6*N1²* Z̅₃* Z̅_{wd}* Z̅_{ws}*Ū_{bs}+6*N1²* Z̅₃* Z̅_{bd}* Z̅₂*Ūₐₛ+3* Z̅_{bs}* Z̅₁*N3²* Z̅_{bd}*Ūₐₛ+6*N1²* Z̅₃*Rd* Z̅_{ws}*Ūₐₛ−3*N1²* Z̅₃*Rd* Z̅_{ws}*Ū_{bs}−N1²* Z̅₂*Ū_{cs}*Rd* Z̅_{bd}−2*N1²* Z̅₂*Ū_{cs}*Rd* Z̅_{wd}+3* Z̅_{bs}* Z̅₁*N3²* Z̅_{bd}*Ū_{bs}+6* Z̅_{bs}* Z̅₁*N3²* Z̅_{wd}*Ū_{cs}+6* Z̅_{bs}* Z̅₁*N3²* Z̅_{wd}*Ūₐₛ−3*N1²* Z̅₃*Rd* Z̅₂*Ū_{cs}+6* Z̅_{bs}* Z̅₁*N3²* Z̅_{wd}*Ū_{bs}+3* Z̅_{bs}* Z̅₁*N3²*Rd*Ū_{cs}+3* Z̅_{bs}* Z̅₁*N3²* Z̅_{bd}*Ū_{cs}+3* Z̅_{bs}* Z̅₁*N3²*Rd*Ū_{bs}+3* Z̅_{bs}* Z̅₁*N3²*Rd*Ūₐₛ+18* Z̅_{bs}*N1²* Z̅₃* Z̅_{wd}*Ūₐₛ+3* Z̅_{bs}*N1²*Ūₐₛ*Rd* Z̅_{bd}−6*N1²* Z̅₃* Z̅_{wd}* Z̅_{ws}*Ū_{cs}+6* Z̅_{bs}*N1²*Ūₐₛ*Rd* Z̅_{wd}+9* Z̅_{bs}*N1²* Z̅₃*Rd*Ūₐₛ+9* Z̅_{bs}*N1²* Z̅₃* Z̅_{bd}*Ūₐₛ−3* Z̅₁*N2²*Ū_{cs}*Rd* Z̅₃+12* Z̅₁*N2²*Ūₐₛ* Z̅_{wd}* Z̅₃−3* Z̅₁*N₂²*Ū_{cs}* Z̅_{bd}* Z̅₃−6* Z̅₁*N2²*Ū_{cs}* Z̅_{wd}* Z̅₃+2* Z̅₁*N2²*Ūₐₛ*Rd* Z̅_{bd}+4* Z̅₁*N2²*Ūₐₛ*Rd* Z̅_{wd}+6* Z̅₁*N2²*Ūₐₛ* Z̅_{bd}* Z̅₃− Z̅₁*N2²*Ū_{cs}*Rd* Z̅_{bd}−2* Z̅₁*N2²*Ū_{cs}*Rd* Z̅_{wd}−3* Z̅₁*N2²*Ū_{bs}*Rd* Z̅₃−N1²* Z̅_{ws}*Ū_{bs}*Rd* Z̅_{bd}−6*N1²* Z̅₃* Z̅_{wd}* Z̅₂*Ū_{bs}−2*N1²* Z̅_{ws}*Ū_{bs}*Rd* Z̅_{wd}+6* Z̅₁*N2²*Ūₐₛ*Rd* Z̅₃+12*N1²* Z̅₃* Z̅_{wd}* Z̅₂*Ūₐₛ−6* Z̅₁*N2²*Ū_{bs}* Z̅_{wd}* Z̅₃−2* Z̅₁*N2²*Ū_{bs}*Rd* Z̅_{wd}−3* Z̅₁*N2²*Ū_{bs}* Z̅_{bd}* Z̅₃−2*N1²* Z̅_{ws}*Ū_{cs}*Rd* Z̅_{wd}+2*N1²* Z̅₂*Ūₐₛ*Rd* Z̅_{bd}+4*N1²* Z̅₂*Ūₐₛ*Rd* Z̅_{wd}− Z̅₁*N2²*Ū_{bs}*Rd* Z̅_{bd}−N1²* Z̅_{ws}*Ū_{cs}*Rd* Z̅_{bd}−3*N1²* Z̅₃* Z̅_{bd}* Z̅_{ws}*Ū_{bs}−N1²* Z̅₂*Ū_{bs}*Rd* Z̅_{bd}−2*N1²* Z̅₂*Ū_{bs}*Rd* Z̅_{wd}+2*N1²* Z̅_{ws}*Ūₐₛ*Rd* Z̅_{bd}+4*N1²* Z̅_{ws}*Ūₐₛ*Rd* Z̅_{wd}−3*N1²* Z̅₃* Z̅_{bd}* Z̅₂*Ū_{cs}+6*N1²* Z̅₃* Z̅_{bd}* Z̅_{ws}*Ūₐₛ)/N1/ Z̅_{bs}/N2/(6* Z̅_{wd}* Z̅₃+3* Z̅_{bd}* Z̅₃+2*Rd* Z̅_{wd}+Rd* Z̅_{bd}+3*Rd* Z̅₃) (Eq. 29)

Ūₐₚ=1/3*(−3*N1²* Z̅₃*Rd* Z̅_{ws}*Ū_{cs}+6*N1²* Z̅₃*Rd* Z̅₂*Ūₐₛ−3*N1²* Z̅₃*Rd* Z̅₂*Ū_{bs}−3*N1²* Z̅₃* Z̅_{bd}* Z̅₂*Ū_{bs}−3*N1²* Z̅₃* Z̅_{bd}* Z̅_{ws}*Ū_{cs}−6*N1²* Z̅₃* Z̅_{wd}* Z̅₂*Ū_{cs}+12*N1²* Z̅₃* Z̅_{wd}* Z̅_{ws}*Ūₐₛ−6*N1²* Z̅₃* Z̅_{wd}* Z̅_{ws}*Ū_{bs}+6*N1²* Z̅₃* Z̅_{bd}* Z̅₂*Ūₐₛ+3* Z̅_{bs}* Z̅₁*N3²* Z̅_{bd}*Ūₐₛ+6*N1²* Z̅₃*Rd* Z̅_{ws}*Ūₐₛ−3*N1²* Z̅₃*Rd* Z̅_{ws}*Ū_{bs}−N1²* Z̅₂*Ū_{cs}*Rd* Z̅_{bd}−2*N1²* Z̅₂*Ū_{cs}*Rd* Z̅_{wd}+3* Z̅_{bs}* Z̅₁*N3²* Z̅_{bd}*Ū_{bs}+6* Z̅_{bs}* Z̅₁*N3²* Z̅_{wd}*Ū_{cs}+6* Z̅_{bs}* Z̅₁*N3²* Z̅_{wd}*Ūₐₛ−3*N1²* Z̅₃*Rd* Z̅₂*Ū_{cs}+6* Z̅_{bs}* Z̅₁*N3²* Z̅_{wd}*Ū_{bs}+3* Z̅_{bs}* Z̅₁*N3²*Rd*Ū_{cs}+3* Z̅_{bs}* Z̅₁*N3²* Z̅_{bd}*Ū_{cs}+3* Z̅_{bs}* Z̅₁*N3²*Rd*Ū_{bs}+3* Z̅_{bs}* Z̅₁*N3²*Rd*Ūₐₛ+18* Z̅_{bs}*N1²* Z̅₃* Z̅_{wd}*Ūₐₛ+3* Z̅_{bs}*N1²*Ūₐₛ*Rd* Z̅_{bd}−6*N1²* Z̅₃* Z̅_{wd}* Z̅_{ws}*Ū_{cs}+6* Z̅_{bs}*N1²*Ūₐₛ*Rd* Z̅_{wd}+9* Z̅_{bs}*N1²* Z̅₃*Rd*Ūₐₛ+9* Z̅_{bs}*N1²* Z̅₃* Z̅_{bd}*Ūₐₛ−3* Z̅₁*N2²*Ū_{cs}*Rd* Z̅₃+12* Z̅₁*N2²*Ūₐₛ* Z̅_{wd}* Z̅₃−3* Z̅₁*N₂²*Ū_{cs}* Z̅_{bd}* Z̅₃−6* Z̅₁*N2²*Ū_{cs}* Z̅_{wd}* Z̅₃+2* Z̅₁*N2²*Ūₐₛ*Rd* Z̅_{bd}+4* Z̅₁*N2²*Ūₐₛ*Rd* Z̅_{wd}+6* Z̅₁*N2²*Ūₐₛ* Z̅_{bd}* Z̅₃− Z̅₁*N2²*Ū_{cs}*Rd* Z̅_{bd}−2* Z̅₁*N2²*Ū_{cs}*Rd* Z̅_{wd}−3* Z̅₁*N2²*Ū_{bs}*Rd* Z̅₃−N1²* Z̅_{ws}*Ū_{bs}*Rd* Z̅_{bd}−6*N1²* Z̅₃* Z̅_{wd}* Z̅₂*Ū_{bs}−2*N1²* Z̅_{ws}*Ū_{bs}*Rd* Z̅_{wd}+6* Z̅₁*N2²*Ūₐₛ*Rd* Z̅₃+12*N1²* Z̅₃* Z̅_{wd}* Z̅₂*Ūₐₛ−6* Z̅₁*N2²*Ū_{bs}* Z̅_{wd}* Z̅₃−2* Z̅₁*N2²*Ū_{bs}*Rd* Z̅_{wd}−3* Z̅₁*N2²*Ū_{bs}* Z̅_{bd}* Z̅₃−2*N1²* Z̅_{ws}*Ū_{cs}*Rd* Z̅_{wd}+2*N1²* Z̅₂*Ūₐₛ*Rd* Z̅_{bd}+4*N1²* Z̅₂*Ūₐₛ*Rd* Z̅_{wd}− Z̅₁*N2²*Ū_{bs}*Rd* Z̅_{bd}−N1²* Z̅_{ws}*Ū_{cs}*Rd* Z̅_{bd}−3*N1²* Z̅₃* Z̅_{bd}* Z̅_{ws}*Ū_{bs}−N1²* Z̅₂*Ū_{bs}*Rd* Z̅_{bd}−2*N1²* Z̅₂*Ū_{bs}*Rd* Z̅_{wd}+2*N1²* Z̅_{ws}*Ūₐₛ*Rd* Z̅_{bd}+4*N1²* Z̅_{ws}*Ūₐₛ*Rd* Z̅_{wd}−3*N1²* Z̅₃* Z̅_{bd}* Z̅₂*Ū_{cs}+6*N1²* Z̅₃* Z̅_{bd}* Z̅_{ws}*Ūₐₛ)/N1/ Z̅_{bs}/N2/(6* Z̅_{wd}* Z̅₃+3* Z̅_{bd}* Z̅₃+2*Rd* Z̅_{wd}+Rd* Z̅_{bd}+3*Rd* Z̅₃) (Eq. 30)

As can be seen from the above equations for Ūₐₚ, Ū_{bp} and Ū_{cp}, in order to calculate primary phase-to-earth voltages from measured secondary voltages Ūₐₛ, Ū_{bs} and Ū_{cs}, for example, the values of the following parameters may be needed:

parameters of the voltage transformers including:

Z̅₁=Impedance of the primary winding

Z̅₂=Impedance of the secondary winding

Z̅₃=Impedance of the tertiary winding

parameters of the circuit connected to the secondary windings including:

Z̅_{ws}=Wiring impedance of the secondary circuit

Z̅_{wn}=Wiring impedance of the secondary circuit, neutral conductor

Z̅_{bs}=Secondary burden impedance

and parameters of the circuit connected to the tertiary windings including:

Z̅_{wd}=Wiring impedance of the open delta

Z̅_{bd}=Tertiary burden impedance

Rd=Ferroresonance (tertiary) damping resistance

Parameter Rd, the resistance of a ferro-resonance damping resistor, value is generally known. This is because it is a separate component and it is dimensioned when ordered. However, one or more values of the impedance parameters are often not known.

According to an exemplary embodiment, the determining of values of impedance parameters related to a transformer configuration, such as the one in FIG. 3, the primary windings 21, 22 and 23 of which are connected to the phases PA, PB and PC of a three phase electric system, includes: conducting an earth fault in the three phase electric system by connecting one of the phases PA, PB or PC of the three phase electric system to earth (e.g., ground); measuring a primary voltage from the faulted phase; measuring secondary voltages from the secondary windings 41, 42, 43; and determining values of one or more impedance parameters related to the transformer configuration on the basis of the measured primary voltage, the measured secondary voltages and an equation relating the primary voltage to the secondary voltages and the one or more impedance parameters related to the transformer configuration.

In case only one impedance parameter value is unknown, then it can be calculated directly on the basis of one of the equations 25 to 30. In case two or more impedance parameter values are unknown, an iterative procedure may be used to determine the values. According to an exemplary embodiment, when the number of the impedance parameters whose values are to be determined is two or more, the determining above includes: finding by iteration such values of the two or more impedance parameters related to the transformer configuration that minimize a difference between the measured value of the primary voltage and a calculated value of the primary voltage obtained on the basis of the equation, the measured secondary voltages and the values of the two or more impedance parameters; and selecting the found values as the determined values of the two or more impedance parameters related to the transformer configuration. In the following, a more detailed example of how the values of the impedance parameters can be determined is given:

First, a trial earth fault is conducted by connecting one of the phases PA, PB or PC of the three phase electric system to earth. In accordance with an exemplary embodiment, some fault resistance may be included in the fault current path so that the amplitude of the faulted phase voltage stays greater than zero. A value of few hundreds of volts (in a 20 kV system) is suggested. A primary voltage Ūₐₚ, Ū_{bp} or Ū_{cp} measurement from the faulted phase is made using, for example, a voltage sensor, which can be installed temporarily or be a part of movable test equipment, for example. The voltage sensor may be based on a resistive divider, for example. Voltage from the sensor may be phase angle and magnitude corrected, if applicable and suggested by the sensor manufacturer. Secondary voltages Ūₐₛ, Ū_{bs} and Ū_{cs} from the secondary windings 41, 42, 43 of the voltage transformers 11, 12, 13 are measured and recorded by, for example, corresponding IEDs (Intelligent Electronic Device) of the substation, and the primary voltage from the sensor is recorded by, for example, a dedicated IED, which can be a part of movable test equipment. Recordings may be synchronized in order to make the evaluation of phase displacement possible. Also an oscilloscope can be used for the recording, especially when the number of the measured three-phase voltage sets is limited, for example, a voltage transformer measurement from only one IED of the station is selected for use in the optimization procedure. Alternatively, the optimization procedure can be conducted for each IED of the substation by using the corresponding recordings from these IEDs. The primary voltage from the voltage sensor is then used as a reference and as the “true” voltage of the electric system. Both the measured primary voltage Ūₐₚ, Ū_{bp} or Ū_{cp} and the voltage transformer voltages Ūₐₛ, Ū_{bs} and Ū_{cs} may be transformed into a phasor form, for example, by using DFT-algorithm (Discrete Fourier Transform). It should be noted that the primary voltage may be measured using other means than a voltage sensor. In fact, any sufficiently accurate way of measuring may be utilized. Thus, the disclosure is not limited to the use of a voltage sensor in the measurement of the primary voltage.

Next, an iterative optimization procedure is conducted, where one of equations 25-30 (or generally any other equation relating the primary voltage to the secondary voltages and the one or more impedance parameters related to the transformer configuration) is utilized. The equation to be used is the applicable phase voltage equation 25-30 that matches the faulted phase of the trial earth fault, i.e. equation 25 or 28 for a trial earth fault in phase PA, equation 26 or 29 for a trial earth fault in phase PB and equation 27 or 29 for a trial earth fault in phase PC. An iterative optimization procedure finds values for two or more of the following parameters:

Z̅₁=Impedance of the primary winding

Z̅₂=Impedance of the secondary winding

Z̅₃=Impedance of the tertiary winding

Z̅_{ws}=Secondary wiring impedance

Z̅_{wn}=Wiring impedance of the neutral conductor of the secondary burden

Z̅_{wd}=Tertiary wiring impedance

Z̅_{bs}=Secondary burden impedance

Z̅_{bd}=Tertiary burden impedance

by minimizing the error: error=Uxp_meas—Uxp_calc, where x is the faulted phase in the trial earth fault. Uxp_meas is the measured primary voltage of the faulted phase and Uxp_calc is the calculated primary voltage of the faulted phase calculated with the applicable equation 25-30. The optimization algorithm should be able to handle multiple variables and desired constrains such that the obtained parameter set is realistic, for example, impedances have positive values. As the optimization is an iterative process, initial guess for parameters could be based on the best knowledge of the system. In accordance with an exemplary embodiment, a parameter set is accepted, which minimizes the error between sensor and voltage transformer measurement. Theoretically this is a parameter set, which gives:

error=Ūₓₚ_{_{—}}meas—Ūₓₚ_{_{—}}calc=0

The applied optimization method can be any known algorithm capable in multivariable optimization, for example, Nelder-Mead algorithm. The Nelder-Mead method is a “simplex” method for finding a local minimum of a function of several variables. It is effective and computationally compact. This function can be found from popular math programs, such as Matlab® or GNU Octave. The algorithm is available in Matlab® and GNU Octave as a function called fminsearch. The source code is also available to be ported into an IED or other platform, for example. The optimization thus may minimize the difference between the measured primary voltage and the calculated value of the primary voltage and returns the corresponding values for the optimized parameters, which provide the minimum.

It should be noted that all the above listed impedance parameters, or just selected ones, can be determined by the optimization procedure. All the other parameters are then fixed as predetermined values. Thus, impedance parameters with predetermined values act as constants in the optimization procedure.

According to an exemplary embodiment, the above determination of the parameter values is repeated for all three phases PA, PB and PC. In other words, the trial earth fault is conducted in each of the three phases, and the values of the one or more impedance parameters are determined separately for each phase using the corresponding equation 25-30. A benefit of determining separate parameter values for all three earth fault conditions is that the obtained parameters are more accurate and take into account better, for example, possible asymmetry in the three phase system.

According to an exemplary embodiment, the obtained values of the impedance parameters are then used in equations 25-30 or corresponding equations in order to compensate for the errors of the voltage transformers when determining the primary voltage Ūₐₚ, Ū_{bp} or Ū_{cp} on the basis of measured secondary voltages Ūₐₛ, Ū_{bs} and Ū_{cs}. In other words, the primary voltages can be calculated using equations 25-30, measured secondary voltages Ūₐₛ, Ū_{bs} and Ū_{cs} and the determined values of the impedance parameters. If the determination of the impedance parameter values is repeated for all three phases PA, PB and PC, then the parameter values to be used in each case may be selected such that for an earth fault in phase PA, PB or PC the impedance parameter values determined during a trial earth fault in the same phase are used. For example, if an earth fault occurs in phase PA, then impedance parameter values may be determined during a trial earth fault in phase PA are used in equation 25-30 for the calculation of one or more primary voltages. If the determination of the impedance parameter values is performed for only one phase PA, PB or PC, then the parameter values thus obtained may be used during an earth fault in any of the phases PA, PB or PC.

An apparatus according to any one of the above embodiments, or a combination thereof, may be implemented as one unit or as two or more separate units that are configured to implement the functionality of the various embodiments. Here the term ‘unit’ refers generally to a physical or logical entity, such as a physical device or a part thereof or a software routine. FIG. 6 illustrates an example of a device 70 that receives as inputs primary voltage Ūₓₚ_{_{—}}meas and secondary voltages Ūₐₛ, Ū_{bs}, Ū_{cs} measured during the trial earth fault and determines and outputs the values of the impedance parameters to be determined as described above, for example. Impedance parameter values that are predetermined may be stored in the device 70. The device 70 may also include means for conducting the trial earth fault such as a control output CONT for controlling a switching device. The device 70 may also include a suitable user interface.

An apparatus according to any one of the embodiments may be implemented by means of a computer or corresponding digital signal processing equipment executing suitable software, for example. Such a computer or digital signal processing equipment may include at least a non-transitory computer- readable recording medium (e.g., a non-volatile memory such as a ROM, hard disk drive, flash memory, etc.) for tangibly recording software and/or program instructions, a working memory (RAM) providing storage area for arithmetical operations and a central processing unit (CPU), such as a general-purpose digital signal processor. The CPU may include a set of registers, an arithmetic logic unit, and a control unit. The control unit is controlled by a sequence of program instructions transferred to the CPU from the RAM. The control unit may contain a number of microinstructions for basic operations. The implementation of microinstructions may vary depending on the CPU design. The program instructions may be coded by a programming language, which may be a high-level programming language, such as C, Java, etc., or a low-level programming language, such as a machine language, or an assembler. The computer may also have an operating system which may provide system services to a computer program written with the program instructions. The computer or other apparatus implementing the disclosure may also include suitable input means and output means. It is also possible to use a specific integrated circuit or circuits, and/or discrete components and devices for implementing the functionality according to any one of the embodiments.

The present disclosure can be implemented in existing system elements, such as one or more IEDs, or by using separate dedicated elements or devices in a centralized or distributed manner. Present devices, such as IEDs, for electric systems may include processors and memory that can be utilized in the functions according to embodiments of the disclosure. Thus, all modifications and configurations required for implementing an embodiment of the disclosure, for example, in existing devices may be performed as software routines, which may be implemented as added or updated software routines. If the functionality of the disclosure is implemented by a processor executing software recorded on a non- transitory computer-readable recording medium, such software can be provided as a computer program product including computer program code which, when run on a computer, causes the computer or a corresponding arrangement to perform the functionality according to the disclosure, as described above. Such a computer program code may be stored or generally embodied on a non-transitory computer readable medium, such as suitable memory, for example, a flash memory or a disc memory from which it is loadable to the unit or units executing the program code. In addition, such a computer program code implementing the disclosure may be loaded to and recorded by the unit or units executing the computer program code via a suitable data network, for example, and it may replace or update a possibly existing program code.

It will be appreciated by those skilled in the art that the present invention can be embodied in other specific forms without departing from the spirit or essential characteristics thereof. The presently disclosed embodiments are therefore considered in all respects to be illustrative and not restricted. The scope of the invention is indicated by the appended claims rather than the foregoing description and all changes that come within the meaning and range and equivalence thereof are intended to be embraced therein.

What is claimed is:

1. A method for determining values of impedance parameters related to a transformer configuration including three single pole voltage transformers each respectively having at least a primary winding, a secondary winding and a tertiary winding, wherein the primary windings are connected to phases of a three phase electric system, and the tertiary windings of the voltage transformers are open- delta connected with each other, the method comprising:
a) conducting an earth fault in the three phase electric system by connecting to earth one of the phases of the three phase electric system;
b) measuring a primary voltage from the faulted phase;
c) measuring secondary voltages from the secondary windings; and
d) determining values of one or more impedance parameters related to the transformer configuration on the basis of the measured primary voltage, the measured secondary voltages, and an equation relating the primary voltage to the secondary voltages and the one or more impedance parameters related to the transformer configuration.

2. The method of claim 1, wherein, when the number of the impedance parameters whose values are determined is two or more, step d) comprises:
finding by iteration values of the two or more impedance parameters related to the transformer configuration that minimize a difference between the measured value of the primary voltage and a calculated value of the primary voltage obtained on the basis of the equation, the measured secondary voltages, and the values of the two or more impedance parameters; and
selecting the found values as the determined values of the two or more impedance parameters related to the transformer configuration.

3. The method of claim 1, wherein steps a) to d) are performed for all three phases.

4. The method of claim 1, wherein the impedance parameters related to the transformer configuration comprise at least one of:
one or more impedance parameters of the voltage transformers;
one or more impedance parameters of a circuit connected to the secondary windings; and
one or more impedance parameters of a circuit connected to the tertiary windings.

5. The method of claim 4, wherein the impedance parameters of the voltage transformers comprise at least one of:
an impedance of the primary winding;
an impedance of the secondary winding; and
an impedance of the tertiary winding.

6. The method of claim 4, wherein the impedance parameters of the circuit connected to the secondary windings comprise at least one of:
a secondary burden impedance; and
a secondary wiring impedance.

7. The method of claim 6, wherein the impedance parameters of the circuit connected to the secondary windings comprise a secondary neutral conductor impedance when the secondary burden impedances are star-connected.

8. The method of claim 4, wherein the impedance parameters of the circuit connected to the tertiary windings comprise at least one of:
a tertiary burden impedance; and
a tertiary wiring impedance.

9. An arrangement for determining values of impedance parameters related to a transformer configuration including three single pole voltage transformers each respectively having at least a primary winding, a secondary winding and a tertiary winding, wherein the primary windings are connected to phases of a three phase electric system, and the tertiary windings of the voltage transformers are open-delta connected with each other, the arrangement comprising:
means for conducting an earth fault in the three phase electric system by connecting to earth one of the phases of the three phase electric system;
means for measuring a primary voltage from the faulted phase;
means for measuring secondary voltages from the secondary windings; and
means for determining values of one or more impedance parameters related to the transformer configuration on the basis of the measured primary voltage, the measured secondary voltages, and an equation relating the primary voltage to the secondary voltages and the one or more impedance parameters related to the transformer configuration.

10. The arrangement of claim 9, wherein, when the number of the impedance parameters whose values are to be determined is two or more, the means for determining are configured to:
find by iteration values of the two or more impedance parameters related to the transformer configuration that minimize a difference between the measured value of the primary voltage and a calculated value of the primary voltage obtained on the basis of the equation, the measured secondary voltages, and the values of the two or more impedance parameters; and
select the found values as the determined values of the one or more impedance parameters related to the transformer configuration.

11. The arrangement of claim 9, wherein the impedance parameters related to the transformer configuration comprise at least one of:
one or more impedance parameters of the voltage transformers;
one or more impedance parameters of a circuit connected to the secondary windings; and
one or more impedance parameters of a circuit connected to the tertiary windings.

12. The arrangement of claim 11, wherein the impedance parameters of the voltage transformers comprise at least one of:
an impedance of the primary winding;
an impedance of the secondary winding; and
an impedance of the tertiary winding.

13. The arrangement of claim 11, wherein the impedance parameters of the circuit connected to the secondary windings comprise at least one of:
a secondary burden impedance; and
a secondary wiring impedance.

14. The arrangement of claim 13, wherein the impedance parameters of the circuit connected to the secondary windings comprise a secondary neutral conductor impedance when the secondary burden impedances are star-connected.

15. The arrangement of claim 11, wherein the impedance parameters of the circuit connected to the tertiary windings comprise at least one of:
a tertiary burden impedance; and
a tertiary wiring impedance.

16. An arrangement for determining values of impedance parameters related to a transformer configuration including three single pole voltage transformers each respectively having at least a primary winding, a secondary winding and a tertiary winding, wherein the primary windings are connected to phases of a three phase electric system, and the tertiary windings of the voltage transformers are open-delta connected with each other, the arrangement being configured to:
conduct an earth fault in the three phase electric system by connecting to earth one of the phases of the three phase electric system;
measure a primary voltage from the faulted phase;
measure secondary voltages from the secondary windings; and
determine values of one or more impedance parameters related to the transformer configuration on the basis of the measured primary voltage, the measured secondary voltages, and an equation relating the primary voltage to the secondary voltages and the one or more impedance parameters related to the transformer configuration.

17. An arrangement for determining values of impedance parameters related to a transformer configuration including three single pole voltage transformers each respectively having at least a primary winding, a secondary winding and a tertiary winding, wherein the primary windings are connected to phases of a three phase electric system, and the tertiary windings of the voltage transformers are open-delta connected with each other, the arrangement comprising:
a processor; and
a memory storing instructions that, when executed by the processor, cause the apparatus to:
conduct an earth fault in the three phase electric system by connecting to earth one of the phases of the three phase electric system;
measure a primary voltage from the faulted phase;
measure secondary voltages from the secondary windings; and
determine values of one or more impedance parameters related to the transformer configuration on the basis of the measured primary voltage, the measured secondary voltages and an equation relating the primary voltage to the secondary voltages and the one or more impedance parameters related to the transformer configuration.
